(19) United States
(12) Patent Application Publication
(10) Pub. No.: US 2013/0107624 A1
(43) Pub. Date: May 2, 2013

(54) SEMICONDUCTOR MEMORY DEVICE AND OPERATION METHOD THEREOF

(71) Applicant: Chang-Won Yang, Gyeonggi-do (KR)

(72) Inventor: Chang-Won Yang, Gyeonggi-do (KR)

(21) Appl. No.: 13/342,474

(22) Filed: Jan. 3, 2012

(30) Foreign Application Priority Data
Oct. 27, 2011 (KR) 10-2011-0110509

(51) Int. Cl. G11C 16/10; G11C 16/04

(52) U.S. Cl. 365/185.03; 365/185.18

(57) ABSTRACT

A programming method of a semiconductor memory device including memory cells of a first data distribution and a second data distribution includes forming an initialization distribution between the first data distribution and the second data distribution, and performing a programming operation by using the initialization distribution as a reference.

### CROSS-REFERENCE TO RELATED APPLICATIONS

The present application claims priority of Korean Patent Application No. 10-2011-0110509, filed on Oct. 27, 2011, which is incorporated herein by reference in its entirety.

### BACKGROUND

1. Field

Exemplary embodiments of the present invention relate to a semiconductor designing technology, and more particularly, to a semiconductor memory device including multi-level cells.

2. Description of the Related Art

In general, semiconductor memory devices are divided into volatile memory devices, such as Dynamic Random Access Memory (DRAM) devices and Static Random Access Memory (SRAM) devices, and non-volatile memory devices, such as Programmable Read Only Memory (PROM) devices, Erasable PROM (EPROM) devices, Electrically EPROM (EEPROM) devices, and flash memory devices. The non-volatile memory devices are different from the volatile memory devices in that the data stored in a memory cell of the non-volatile memory device is retained even after a predetermined time passes.

That is, in the non-volatile memory devices, the data stored in a memory cell is retained even after a predetermined time passes, whereas, in the volatile memory devices, the data stored in a memory cell is lost. The volatile memory devices perform a refresh operation essentially to maintain data. Furthermore, due to the above feature, the non-volatile memory devices do not require a fresh operation. Since the feature of the non-volatile memory devices is more desirable in a low power consumption and high integration application, the non-volatile memory devices have be widely used as storage media of portable devices.

Meanwhile, a flash memory device among the non-volatile memory devices stores a data in a memory cell through a programming operation and an erasing operation. Herein, the programming operation is an operation for accumulating electrons in a floating gate of a transistor that constitutes a memory cell, while the erasing operation is an operation for discharging electrons accumulated in a floating gate of a transistor to a substrate. The flash memory device accumulates or discharges electrons to or from a floating gate through the operations, and each memory cell has a data distribution corresponding to ‘0’ data or ‘1’ data.

As described above, one memory cell stores a data of ‘0’ or ‘1’. That is, one memory cell stores one-bit data and the memory cell is referred to as a single level cell. Recently, however, a method of storing a data of more than one bit in one memory cell is being introduced. Such a memory cell may be referred to as a multi-level cell. A single level cell may require one decision voltage to decide whether the data stored in the memory cell is ‘0’ or ‘1’, and a multi-level cell may require a plurality of decision voltages to decide whether the data stored in the memory cell is, for example, ‘00’, ‘01’, ‘10’, or ‘11’.

Meanwhile, as semiconductor memory device fabrication technology makes progress, there are many things to be considered in designing of the memory device. Among them are interference and disturbance. The interference and disturbance are major factors that increase the failure rate of semiconductor memory devices.

FIG. 1 is a diagram illustrating a programming operation of a conventional flash memory device. The drawing describes a data distribution according to each operation of a multi-level cell.

Referring to FIG. 1, a mark (A) shows a data distribution when an erasing operation is performed onto a multi-level cell, and a mark (B) shows a data distribution corresponding to ‘1’ data and ‘0’ data when a lower bit programming operation is performed onto a multi-level cell. A mark (C) shows a data distribution corresponding to ‘11’ data, ‘10’ data, ‘01’ data, and ‘00’ data when an upper bit programming operation is performed onto a multi-level cell. In other words, since one multi-level cell may be programmed with, for example, a two-bit data, which includes a Least Significant Bit (LSB) and a Most Significant Bit (MSB), it may be possible to program ‘11’ data, ‘10’ data, ‘01’ data, and ‘00’ data according to data distribution.

Meanwhile, the data distribution of a conventional flash memory device has a range DTP1 from ‘00’ data to ‘11’ data. Generally, as the range DTP1 is increased, interference and disturbance may be increased as well, and the greater interference and disturbance may decrease the reliability of a semiconductor memory device.

### SUMMARY

Exemplary embodiments of the present invention are directed to a semiconductor memory device that has a minimized data distribution range.

In accordance with an exemplary embodiment of the present invention, a programming method of a semiconductor memory device including memory cells of a first data distribution and a second data distribution includes forming an initialization distribution between the first data distribution and the second data distribution, and performing a programming operation by using the initialization distribution as a reference.

The performing of the programming operation may include forming the first data distribution by applying a first programming voltage to the initialization distribution, and forming the second data distribution by applying a second programming voltage which is different from the first programming voltage to the initialization distribution.

In accordance with another exemplary embodiment of the present invention, a programming method of a semiconductor memory device includes setting an initialization distribution before a programming operation, and forming one data distribution among a plurality of data distributions by applying a negative voltage to the initialization distribution.

The programming method may further include forming the other data distributions among the multiple data distributions by applying another programming voltage to the initialization distribution, wherein the second programming voltage is different from the negative voltage.

In accordance with yet another exemplary embodiment of the present invention, a semiconductor memory device includes a programming voltage generator configured to generate a first programming voltage for forming a first data distribution and a second programming voltage for forming a second data distribution in response to a data to be stored during a programming operation, an initialization voltage generator configured to generate an initialization voltage having a voltage level between the first programming voltage and the second programming voltage during an initialization operation, and a memory cell array configured to receive the first programming voltage, the second programming voltage, and the initialization voltage and form corresponding data distributions.

The first programming voltage may include a negative voltage, and the second programming voltage comprises a positive voltage.

### BRIEF DESCRIPTION OF THE DRAWINGS

FIG. 1 is an explanatory diagram illustrating a programming operation of a conventional flash memory device.

FIG. 2 is a block diagram illustrating a portion of a semiconductor memory device in accordance with an exemplary embodiment of the present invention.

FIG. 3 an explanatory diagram showing a programming operation of a flash memory device in accordance with an exemplary embodiment of the present invention.

FIG. 4 is a flowchart describing a process for forming initialization distribution in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

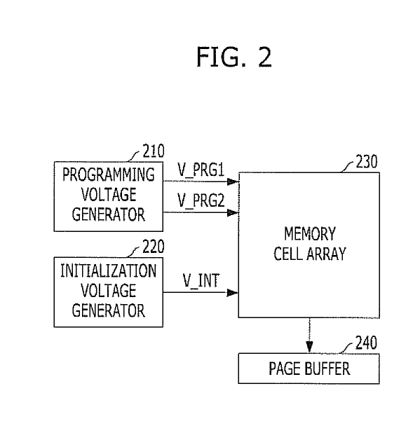

FIG. 2 is a block diagram illustrating a portion of a semiconductor memory device in accordance with an exemplary embodiment of the present invention.

Referring to FIG. 2, the semiconductor memory device includes a programming voltage generator 210, an initialization voltage generator 220, a memory cell array 230, and a page buffer 240.

The programming voltage generator 210 generates a first programming voltage V_PRG1 and a second programming voltage V_PRG2. Herein, the first programming voltage V_PRG1 is a negative voltage, and the second programming voltage V_PRG2 is a positive voltage. Subsequently, the initialization voltage generator 220 generates an initialization voltage V_INT during an initialization operation. Herein, the initialization voltage V_INT may have a voltage level between the first programming voltage V_PRG1 and the second programming voltage V_PRG2, and it may also have diverse voltage level according to a design choice. The initialization voltage V_INT may be designed to be higher than the first programming voltage V_PRG1.

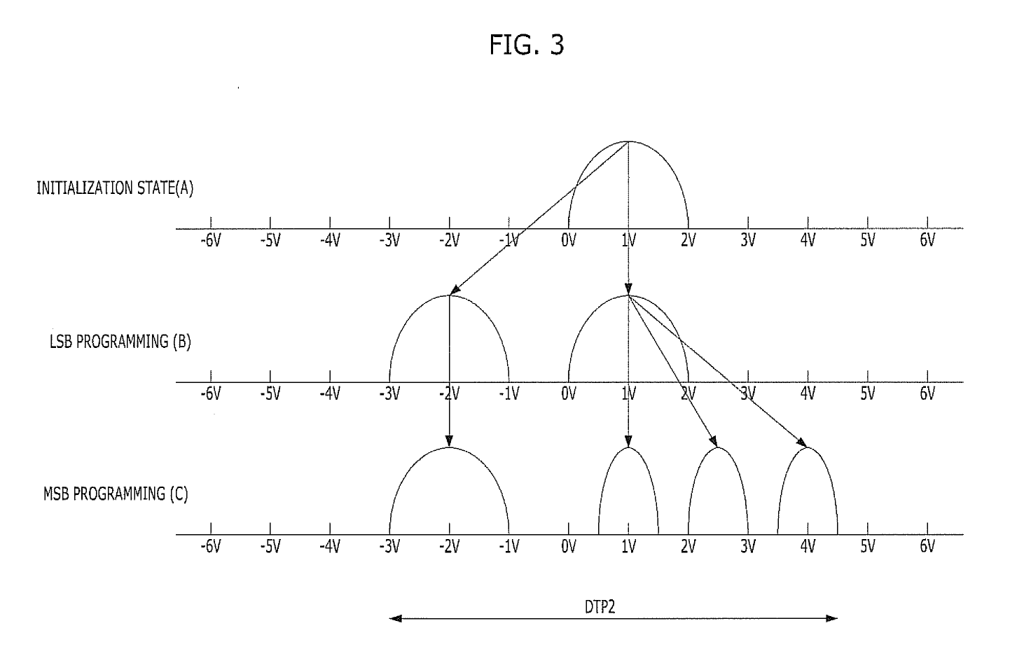

Meanwhile, the memory cell array 230 includes a plurality of memory cells, and the memory cells have a data distribution corresponding to an applied voltage. In other words, the memory cell array 230 receives the first programming voltage V_PRG1 and the second programming voltage V_PRG2 to form data distributions corresponding to the first programming voltage V_PRG1 and the second programming voltage V_PRG2, and the memory cell array 230 receives the initialization voltage V_INT to form an initialization distribution between the data distributions corresponding to the first programming voltage V_PRG1 and the second programming voltage V_PRG2. Although to be described later with reference to FIG. 3, the initialization distribution is positioned on the right side of the data distribution formed according to the first programming voltage V_PRG1. Subsequently, the page buffer 240 decides the data distribution formed on the memory cell array 230 and outputs it as data during a read operation.

FIG. 3 illustrates a programming operation of a flash memory device in accordance with an exemplary embodiment of the present invention. The drawing shows a data distribution of a multi-level cell for each operation.

Referring to FIG. 3, a mark (A) shows a data distribution when an initialization operation is performed onto a multi-level cell, and a mark (B) shows a data distribution corresponding to ‘1’ data (in the range form approximately −3V to approximately −1V) and ‘0’ data (in the range from approximately 0V to approximately 2V) when a lower bit programming operation is performed onto a multi-level cell. A mark (C) shows a data distribution corresponding to ‘11’ data (in the range from approximately −3V to approximately −1V), ‘10’ data (in the range from approximately 0.5V to approximately 1.5V), ‘01’ data (in the range from approximately 2V to approximately 3V), and ‘00’ data (in the range from approximately 3.5V to approximately 4.5V) when an upper bit programming operation is performed onto a multi-level cell.

The semiconductor memory device in accordance with the exemplary embodiment of the present invention initializes the data distribution of a memory cell during the (A) operation. Subsequently, the semiconductor memory device generates a lower bit, which is ‘1’ data, by applying the first programming voltage V_PRG1, which is a negative voltage, to the memory cell array 230 during the (B) operation. The semiconductor memory device generates ‘10’ data, ‘01’ data, and ‘00’ data by applying the second programming voltage V_PRG2, which is a positive voltage, to the memory cell array 230 during the (C) operation. Herein, the second programming voltage V_PRG2 for forming the ‘10’ data, ‘01’ data, and ‘00’ data may have different voltage levels.

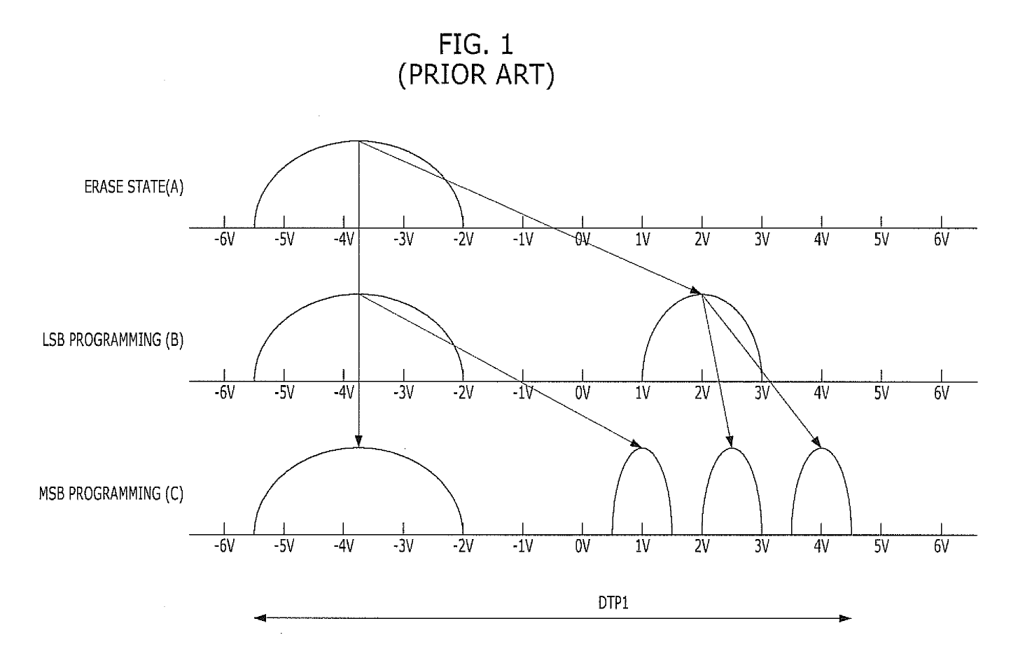

As shown, the data distribution of the semiconductor memory device in accordance with an exemplary embodiment of the present invention has a range DTP2 from ‘00’ data to ‘11’ data. Comparing the range DTP2 of FIG. 3 with the range DTP1 of FIG. 1, it may be seen that the range DTP2 of FIG. 3 is smaller than the range DTP1 of FIG. 1.

Meanwhile, although a ‘00’ data distribution is formed on the left side of the initialization distribution in FIG. 3, the semiconductor memory device in accordance with the exemplary embodiment of the present invention may form more data distributions other than the ‘00’ data distribution on the left side of the initialization distribution. That is, as three data distributions are formed in a group on the right side of the initialization distribution, data distributions may be formed in a group on the left side of the initialization distribution.

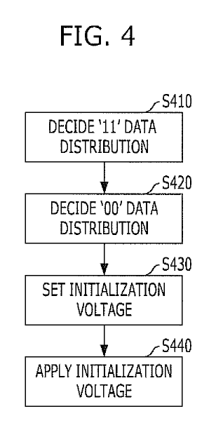

FIG. 4 is a flowchart describing a process for forming initialization distribution in accordance with an exemplary embodiment of the present invention.

Referring to FIG. 4, when the initialization distribution is formed, a ‘11’ data distribution is decided first in step S410, and then a ‘00’ data distribution is decided in step S420. That is, the data distribution on the left-most side and the data distribution on the right-most side are first decided. In step S430, the voltage level of the initialization voltage is set based on the decision result. When the initialization voltage set as above is applied to a memory cell array in step S440, the initialization distribution of a corresponding memory cell is formed. The semiconductor memory device in accordance with the exemplary embodiment of the present invention forms a desired data distribution by applying a first programming voltage V_PRG1 and a second programming voltage V_PRG2 to the initialization distribution that is set as above.

As described above, the semiconductor memory device in accordance with the exemplary embodiment of the present invention may have a minimized range of a data distribution. This means that the interference and disturbance are small, which may increase reliability of the semiconductor memory device.

According to an exemplary embodiment of the present invention, the interference and disturbance occurring in a semiconductor memory device may be reduced so as to increase the reliability of the semiconductor memory device.

While the present invention has been described with respect to the specific embodiments, it will be apparent to those skilled in the art that various changes and modifications may be made without departing from the spirit and scope of the invention as defined in the following claims.

What is claimed is:

1. A programming method of a semiconductor memory device including memory cells of a first data distribution and a second data distribution, comprising:
forming an initialization distribution between the first data distribution and the second data distribution; and
performing a programming operation by using the initialization distribution as a reference.

2. The programming method of claim 1, wherein the performing of the programming operation comprises:
forming the first data distribution by applying a first programming voltage to the initialization distribution; and
forming the second data distribution by applying a second programming voltage to the initialization distribution, wherein the second programming voltage is different from the first programming voltage.

3. The programming method of claim 2, wherein the first programming voltage comprises a negative voltage, and the second programming voltage comprises a positive voltage.

4. The programming method of claim 1, wherein each of the first data distribution and the second data distribution comprises a plurality of data distributions.

5. The programming method of claim 1, wherein the forming of the initialization distribution comprises:
deciding the first data distribution and the second data distribution to produce a decision result;
setting an initialization voltage based on the decision result; and
applying the initialization voltage to the memory cells.

6. A programming method of a semiconductor memory device, comprising:
setting an initialization distribution before a programming operation; and
forming one data distribution among a plurality of data distributions by applying a negative voltage to the initialization distribution.

7. The programming method of claim 6, further comprising:
forming the other data distributions among the multiple data distributions by applying another programming voltage to the initialization distribution, wherein another programming voltage which is different from the negative programming voltage.

8. The programming method of claim 6, wherein the data distribution formed in response to the negative programming voltage comprises a plurality of data distributions.

9. A semiconductor memory device, comprising:
a programming voltage generator configured to generate a first programming voltage for forming a first data distribution and a second programming voltage for forming a second data distribution in response to a data to be stored during a programming operation;
an initialization voltage generator configured to generate an initialization voltage having a voltage level between the first programming voltage and the second programming voltage during an initialization operation; and
a memory cell array configured to receive the first programming voltage, the second programming voltage, and the initialization voltage and form corresponding data distributions.

10. The semiconductor memory device of claim 9, wherein the first programming voltage comprises a negative voltage, and the second programming voltage comprises a positive voltage.

11. The semiconductor memory device of claim 9, wherein the data distribution formed in response to the initialization voltage is disposed between the data distributions that are respectively formed in response to the first programming voltage and the second programming voltage.

12. The semiconductor memory device of claim 9, wherein the memory cell array comprises a plurality of multi-level cells.

13. The semiconductor memory device of claim 9, further comprising:
a page buffer configured to decide a data distribution formed in the memory cell array and output a data.
